(19) United States
(12) Patent Application Publication
(10) Pub. No.: US 2014/0021939 A1
(43) Pub. Date: Jan. 23, 2014

(54) CURRENT-MEASURING DEVICE

(71) Applicants: Alexey Dobrenko, Konstanz (DE); Pavel Larionov, Konstanz (DE); Thomas Hauser, Konstanz (DE)

(72) Inventors: Alexey Dobrenko, Konstanz (DE); Pavel Larionov, Konstanz (DE); Thomas Hauser, Konstanz (DE)

(73) Assignee: SUNWAYS AG PHOTOVOLTAIC TECHNOLOGY, Konstanz (DE)

(21) Appl. No.: 13/979,948

(22) PCT Filed: Jan. 13, 2012
(86) PCT No.: PCT/EP2012/050498

§ 371 Date: Oct. 7, 2013

(30) Foreign Application Priority Data
Jan. 17, 2011 (DE) 10 2011 002 756.4

(51) Int. Cl. G01R 19/00

(52) U.S. Cl. CPC G01R 19/00
USPC 324/127

(57) ABSTRACT

The invention relates to a current measuring device for detecting a current flowing through a power line, said device comprising: a magnetic loop for receiving the power line; an excitation device designed to magnetise the magnetic loop by means of a periodic signal; a first current sensor designed to detect an exciting current flowing in the excitation device on the basis of the periodic signal and/or the current to be detected; and a determination device that determines a shift of the detected exciting current on the current axis, said shift being caused by the current, and, as a result, deduces the intensity of the current to be detected. The invention also relates to a solar inverter and to a method for detecting a current.

### FIELD OF THE INVENTION

The invention relates to a current-measuring device for detecting a current flowing through a power supply line. The invention further relates to a solar inverter and to a method for detecting a current.

### TECHNICAL BACKGROUND

There are a variety of applications in which low direct currents (DC) and alternating currents (AC) need to be detected very precisely. In particular, this is the case in electrical residual-current devices (or RCDs for short), by means of which a residual current or generally a differential current can be measured. An RCD of this type can be for example a residual-current circuit breaker or a shut-off device of a solar inverter, in particular of a transformerless solar inverter.

Current sensors are provided to measure a current in electrical circuits. These current sensors work on the basis of an open magnetic circuit and a sensor which is sensitive to magnetic fields, for example a Hall sensor, which is placed in the air gap of the magnetic circuit. This type of current sensor is problematic in the case of magnetic fields occurring due to external influences, which fields penetrate through the air gap of the magnetic circuit into the magnetic circuit. In these cases, the measurement results generated by current sensors of this type are distorted to a greater or lesser extent. These current sensors are therefore of only limited suitability for measuring low and very low currents, for example currents in a range of up to 50 mA.

In particular for a residual current detection in which very low differential currents are to be measured, current sensors based on a transformer principle are generally used. In these sensors, the alternating magnetic field of a conductor through which a differential current flows induces an alternating current in a coil. This alternating current is proportional to the current to be measured, and can be detected for example by a precision resistor. These sensors have a very simple construction in terms of circuitry, and do not require an external power supply. In any case, as a result of the measuring principle, these current sensors cannot be designed to measure direct currents. Current sensors of this type are unsuitable for use in electrical RCDs.

In order to detect the direct currents at the same time as alternating currents, current sensors which are based on a magnetic multivibrator method are usually used. In the case of these sensors, the pulse-width ratio of a carrier voltage is influenced by the current to be measured. However, these sensors have a lower sensitivity, and the result of the current measurement is influenced by the supply voltage of the current sensor.

The direct- and alternating-current sensors available today, which are also referred to as universal sensors and which are designed to measure even very low currents with a sufficiently high level of precision, have a very complex construction in terms of circuitry, and are therefore very expensive.

### SUMMARY OF THE INVENTION

Against this background, the problem addressed by the present invention is that of providing a simple direct- and alternating-current sensor.

This problem is solved according to the invention by a current-measuring device having the features of claim 1 and/or by a solar inverter having the features of claim 14 and/or by a method having the features of claim 15.

According thereto, the following is provided:
a current-measuring device for detecting a current flowing through a power supply line, comprising a magnetic loop for receiving the power supply line; comprising an excitation device which is designed to magnetise the magnetic loop by means of a periodic signal of such a type that the exciting current constantly fluctuates between two saturation limits; comprising a first current sensor which is designed to detect an exciting current flowing in the excitation device as a result of the periodic signal or the current to be detected; comprising a determining means, which determines a shift of the detected exciting current on the current axis caused by the current and derives therefrom the current strength of the current to be detected.
A solar inverter, in particular a transformerless solar inverter, comprising a current-measuring device according to the invention.
A method for detecting a current, in particular by means of a current-measuring device according to the invention, comprising the steps of: magnetizing a magnetic loop for receiving a power supply line by means of a periodic signal via an excitation device; guiding a power supply line through the magnetic loop; energising the power supply line with the current to be detected; detecting an exciting current which flows in the excitation device as a result of the periodic signal or as a result of the current; deriving a current strength of the current to be detected from the shift of the detected exciting current on the current axis.

The present invention is based on the knowledge that an exciting current flowing through the excitation device is influenced not only by the periodic signal, but also by the current flowing through the power supply line. The present invention is now based on the concept of taking this knowledge into account and evaluating a shift of the saturation limits of the exciting current which is caused by the current flowing through the power supply line, and deriving therefrom the current strength of the current flowing through the power supply line.

The periodic signal impresses a periodic current in the excitation device in case no current flows in the power supply line, said periodic current having a course which is symmetrical to zero on the current axis.

If a current to be detected flows through the power supply line, the course of the periodic exciting current is shifted into the positive or negative range on the current axis. The direction of this shift depends on the sign of the current in the power supply line, and the magnitude of this shift is proportional to the current strength of the current to be detected in the power supply line.

The present current-measuring device detects the course of the exciting current in the excitation device by means of a current sensor and determines the shift of the periodic course of the exciting current on the current axis relative to zero using a determining means, and derives therefrom the current strength of the current to be detected. The current sensor, which detects the course of the exciting current, can be designed in its simplest configuration as a simple precision or shunt resistor. In further embodiments, the current sensor can also be constructed in any other manner.

Using the current-measuring device according to the invention, it is possible to provide a very simple but nevertheless very precise direct- and alternating-current sensor which cannot be influenced, or at least can only be influenced to a very small extent, by externally coupled magnetic fields. The direct- and alternating-current sensor can in particular be used in applications of the type which require a very high level of precision, but at the same time are not free from external interference fields.

Advantageous configurations and developments emerge from the further dependent claims and from the description with reference to the figures of the drawings.

In a preferred embodiment, the excitation device comprises an excitation generator, which generates a periodic voltage as a periodic signal such that the exciting current from the excitation generator constantly fluctuates between two saturation limits. The excitation device further comprises an exciting coil which is designed to magnetise the magnetic loop by means of the periodic voltage. The excitation generator can be designed as an alternating current source which generates a periodic voltage which is rectangular, sinusoidal, or any other shape. In alternative embodiments, however, the excitation generator can also generate a periodic signal via an arrangement of switching elements, such as a full or half bridge. A construction of this type makes it possible to influence the course of the periodic voltage, for example on the basis of the field of application of the current-measuring device. If an individual exciting coil is used to magnetise the magnetic loop by means of the periodic signal, this advantageously results in a particularly simple construction of the current-measuring device. If, however, a transformer device is used instead of the individual exciting coil to magnetise the magnetic loop, the excitation device can be flexibly adapted to the application in question.

In a further embodiment, the determining means comprises a time-measuring device which measures, for each period of the periodic exciting current, a first time period in which the detected exciting current has a positive value. The time-measuring device measures, for each period of the periodic exciting current, a second time period in which the detected exciting current has a negative value. The determining means comprises an integration means which integrates a difference between the first time period measured and the second time period measured as a measure of the current to be detected. A configuration of this type of the determining means makes it possible to achieve a very simple construction in terms of circuitry by using simple analogue components. If the first current sensor is implemented for example as a shunt resistor, the time-measuring device can be implemented for example as a simple comparator. The comparator outputs a positive signal if a positive voltage drops across the shunt resistor and the comparator outputs a negative signal if a negative voltage drops across the shunt resistor. The integration means can then be implemented as a low pass which receives the output signal of the comparator as an input signal and which generates an output signal which is a measure of the current to be detected.

In a further preferred configuration, the determining means comprises a filter device which filters a direct current component out of the detected exciting current as a measure of the current to be detected. The direct current component of the detected exciting current reflects the shift of the course of the exciting current on the current axis. Thus, the output signal of the filter is also a measure of the current strength of the current to be detected. If a filter device is used which filters the direct current component of the exciting current out of the exciting current, a time-measuring device and an integration means can advantageously also be omitted. In addition, it is possible to construct the current-measuring device in a particularly simple manner in terms of circuitry, since a filter of this type can be constructed from simple analogue components, such as resistors, inductors etc.

In a preferred development, a compensation means is provided which is designed to additionally magnetise the magnetic loop on the basis of the detected current strength. Without a compensation means, above a certain strength of the current to be detected, the material of the magnetic loop becomes saturated. In this case, a further increase in the current does not lead to further magnetisation of the magnetic loop, and thus does not lead to further change in the exciting current, and therefore, above this current threshold, the current to be detected cannot be detected without a compensation means. The compensation means is configured such that it compensates for the magnetisation which the current to be detected causes in the magnetic loop. This thereby prevents the material of the magnetic loop from becoming saturated. For the current-measuring device, this means a linearization of the measuring range of the current-measuring device. A current to be detected, which would have magnetised the material of the magnetic loop to the point of saturation without the compensation means, can nevertheless be detected. In an embodiment of this type of the current-measuring device, a compensating current which flows in the compensation means is proportional to the current to be detected and can thus be used as a measure of the current strength of the current to be detected. As a result, the measuring range can be extended to a certain extent. The compensating current can be measured using a current sensor, for example a shunt resistor. A second positive effect when using the compensation means is that the magnetic loop is always located at the same operating point, and thus carries out the measurement regardless of the non-linearity of the magnetic loop.

In a further embodiment, the compensation means comprises a compensation generator which is designed to generate a compensating voltage on the basis of the current strength. The compensation means comprises a compensation coil which is designed to additionally magnetise the magnetic loop in the opposite direction by means of the generated compensating voltage. If a compensation generator, for example in the form of an operational amplifier, is used to generate the compensating voltage, said generator can directly process the signal of the determining means. This makes it possible to construct the current-measuring device in a particularly simple manner.

In alternative configurations, the compensation generator can comprise a digital circuit which generates the compensating voltage on the basis of digital switching signals or control commands. This makes it possible to integrate at least part of the compensation generator into a program-controlled device, such as a microprocessor. If there is a program-controlled device in the application with the current-measuring device, which program-controlled device has sufficient computing resources to carry out the function of the compensation generator, a very compact current-measuring device can be provided. In particular, no additional components have to be used for the compensation generator. If a separate digital circuit is provided for the compensation generator, a very flexibly controllable compensation generator can be used.

In a further embodiment, a calibration device is provided which is designed to magnetise the magnetic loop. The calibration device is further designed to generate a calibrated current strength of the current to be detected by the current-measuring device on the basis of the compensating current being set due to the compensating voltage in the compensation coil.

In one development, the compensation means comprises a second current sensor which is designed to detect the compensating current flowing in the compensation coil. The calibration device further comprises a control means which periodically stores a first current strength of the compensating current at predetermined time intervals and then generates a control signal for start-up. The calibration device further comprises a current source which generates a defined current on the basis of the control signal. In addition, a calibration coil is provided which is designed to additionally magnetise the magnetic loop on the basis of the defined current. The control means is designed to store a second current strength of the compensating current when the magnetic loop is magnetised by means of the defined current. The control means is designed to determine a calibrated current strength from the difference between the first stored current strength and the second stored current strength. By means of a configuration of this type of the calibration device, a calibration of the current-measuring device can be carried out at any time, and thus a higher level of precision of the measuring result can be achieved. In an arrangement of this type, the control means generates a signal which contains the calibrated strength of the current to be measured. This signal can be an analogue signal or a digital signal.

In a further preferred embodiment, the integration means is designed as an analogue circuit. This makes it possible to construct the integration means in a very simple and robust manner. In addition, the integration means can be coupled directly to an analogue time-measuring device and an analogue compensation means, without having to carry out a signal conversion.

In a further embodiment, an integrated circuit, in particular a program-controlled device, is provided, which comprises the integration means. An integrated circuit of this type, in particular a program-controlled device, can be adapted very flexibly to new requirements. For example, various selectable characteristics or multiplication factors can be entered in the integrated circuit or the program-controlled device and can influence the output signal of the integration means. Alternatively, a program code which comprises the integration means can also be exchanged, and the function thereof thus adapted to varying requirements.

In one embodiment, the magnetic loop is designed as a magnetic loop without an air gap. Constructing the magnetic loop without an air gap offers the advantage that the sensitivity of the current-measuring device to external interference fields is very low. A very precise and robust current measurement can thus be provided. The current-measuring device according to the invention is, however, not limited thereto, and can for example also be used in magnetic loops having an air gap.

In one embodiment, the exciting coil is designed as a single or double coil. A compensation coil which is suitable for the field of application in question can thereby be provided which increases the flexibility of the current-measuring device. In further embodiments, both the compensation coil and the calibration coil can each be designed as a single or a double coil. It would also be conceivable to use triple or generally multiple coils.

In a particularly preferred embodiment, the method according to the invention has at least two operating modes. In a first operating mode, direct currents (DC) can be detected by means of the current-measuring device, and in a second operating mode, alternating currents (AC) can be detected by means of the current-measuring device. The current-measuring device according to the invention is thus designed to detect AC and DC currents and can therefore be used universally. Preferably, a third operating mode is provided in which direct and alternating currents can be detected at the same time by means of the current-measuring device.

Where appropriate, the above-mentioned configurations and developments can be combined in any manner. Further possible configurations, developments and implementations of the invention also include combinations, which are not explicitly mentioned, of features of the invention which have been described previously or are described in the following with reference to the embodiments. In particular, in this case, a person skilled in the art will also add individual aspects as improvements or supplements to the basic form of the present invention.

### CONTENTS OF THE DRAWINGS

The present invention is described in greater detail in the following on the basis of the embodiments shown in the schematic figures of the drawings, in which:

FIG. 1 is a block diagram of an embodiment of a current-measuring device according to the invention;

FIG. 2 is a block diagram of a further embodiment of a current-measuring device according to the invention;

FIG. 3 is a block diagram of a further embodiment of a current-measuring device according to the invention;

FIG. 4 is a block diagram of an embodiment of an excitation device according to the invention;

FIG. 5 is a block diagram of a further embodiment of an excitation device according to the invention;

FIG. 6 is a block diagram of a solar inverter according to the invention;

FIG. 7 is a flow chart of an embodiment of a method according to the invention.

The appended drawings are intended to provide further understanding of the embodiments of the invention. They illustrate embodiments and, in conjunction with the description, help to explain principles and concepts of the invention. Other embodiments and many of the advantages mentioned become apparent in view of the drawings. The elements in the drawings are not necessarily shown to scale.

In the drawings, like, functionally equivalent and identically operating elements, features and components are provided with like reference signs in each case, unless stated otherwise.

### DESCRIPTION OF EMBODIMENTS

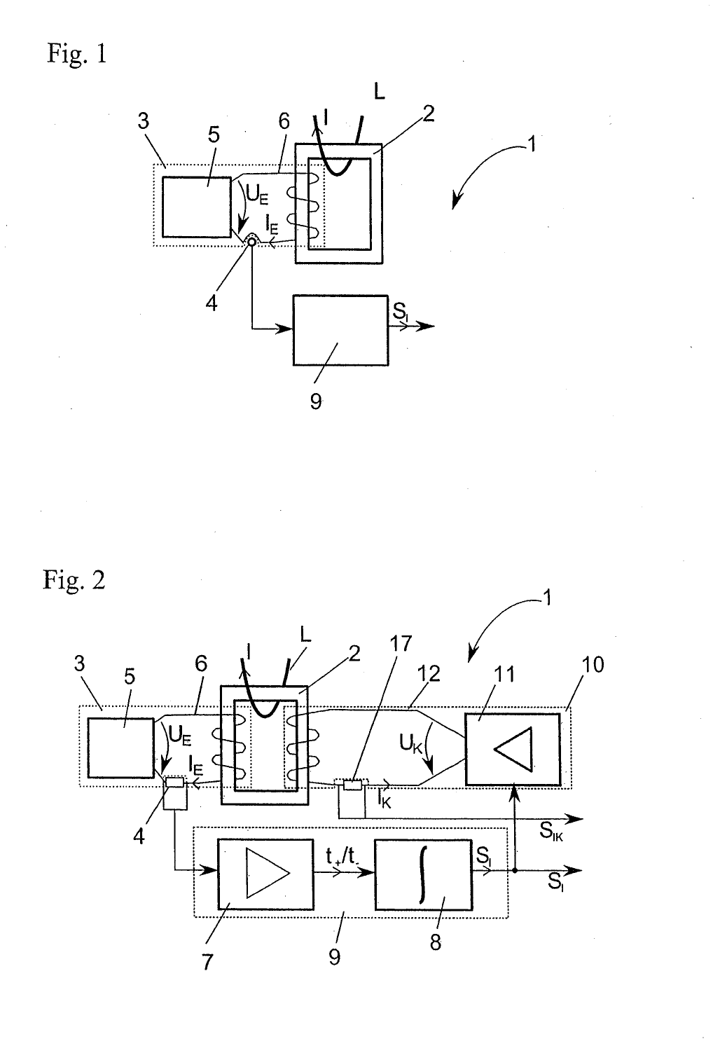

FIG. 1 shows a block diagram of an embodiment of a current-measuring device 1 according to the invention. The current-measuring device 1 comprises a magnetic loop 2 which is coupled to an excitation device 3 and through which a power supply line L extends. The excitation device 3 comprises an excitation generator 5, which generates a periodic signal U_{E} as a periodic voltage U_{E}. The periodic signal U_{E} is set such that the exciting current constantly fluctuates between two saturation limits. The excitation device 3 further comprises an exciting coil 6, which is designed to magnetise the magnetic loop 2 by means of the periodic voltage U_{E}. In addition, a first current sensor 4 is provided which detects an exciting current I_{E} which forms within the excitation device 3 when said device magnetizes the magnetic loop 2 by means of the periodic voltage U_{E}. Finally, a determining means 9 is provided which receives the present current strength of the exciting current I_{E} from the first current sensor 4 and derives therefrom the present current strength S_{I} of the current I.

The current-measuring device 1 shown here is designed to measure current strengths in a range of up to 500 mA. In further embodiments, the current-measuring device can measure currents in a range of up to several amps, preferably currents of up to 10 A.

In the embodiment of a current-measuring device 1 according to the invention shown in FIG. 1, the magnetic loop 2 is shown as a square magnetic loop without an air gap, and consists of a ferromagnetic material. In a further configuration, the magnetic loop 2 is designed as a round magnetic loop 2. It would, of course, also be conceivable for the magnetic loop 2 to be any other shape, for example a rectangular, oval or polygonal magnetic loop 2 or a magnetic loop with an air gap.

The excitation device 3 magnetizes the magnetic loop 2 in the embodiment shown in FIG. 1 by means of the periodic voltage U_{E}, which leads to a periodically running exciting current I_{E} within the exciting coil 6. The frequency of the periodic voltage U_{E} and thus also the frequency of the exciting current I_{E}, which is the same as the frequency of the periodic voltage U_{E}, are 10 kHz in this embodiment. Since the magnetic properties of the magnetic loop 2 are unstable and change to a greater or lesser extent according to the temperature, the frequency can also change. However, this has little to no influence on the measurement.

In further embodiments, the frequencies can lie in a range of from 1 kHz to 1 MHz, in particular in a range of from 5 kHz to 100 kHz.

The periodic voltage U_{E} in the excitation device 3 has for example an RMS value of 10 volts. A current having an RMS value of 10 mA is thus set as an exciting current. The amplitude of the periodic voltage U_{E} is in any case less relevant for the application. What is essential is that the necessary exciting current can be set by means of the voltage U_{E}.

The first current sensor 4 from FIG. 1 is designed as a directly measurable, passive first current sensor 4. A directly measurable, passive first current sensor 4 makes it possible to detect the exciting current I_{E} in a particularly simple and precise manner.

FIG. 2 shows a block diagram of a further embodiment of a current-measuring device 1 according to the invention.

The current-measuring device 1 shown in FIG. 2 differs from the current-measuring device 1 shown in FIG. 1 in that the determining means 9 comprises a time-measuring device 7 which receives the signal of the first current sensor 4 and generates two signals t₊ and t₋ therefrom, which are evaluated by an integration means 8, which derives therefrom the current strength S_{I} of the current I to be detected. The current strength S_{I} is conveyed outwards directly as an output variable of the determining means 9 and can be used in a configuration as a measure of the strength of the current I. The current strength S_{I} is further conveyed to a compensation means 10, which comprises a compensation generator 11 and a compensation coil 12. The compensation generator 11 generates a compensating voltage U_{K} on the basis of the current strength S_{I}. The compensation coil 12 magnetizes the magnetic loop 2 by means of this compensating voltage U_{K}, whereby a compensating current I_{K} is set in the compensation coil 12. In addition, a second current sensor 17 is provided which detects the strength S_{IK} of the compensating current I_{K} which flows in the compensation coil 12. In FIG. 2, the first current sensor 4 is provided as a first shunt resistor 4, and the second current sensor 17 as a second shunt resistor 17.

The compensation generator 11 is dimensioned such that it generates the compensating voltage U_{K} in such a manner that the magnetic flow generated in the magnetic loop 2 by the compensation coil 12 within the magnetic coil 2 has the opposite sign to and the same value as the magnetic flow which is generated by the current I, which flows in the power supply line L. The magnetic flow in the magnetic loop 2 is thereby corrected to zero. In an arrangement of this type, the strength S_{IK} of the compensating current I_{K} flowing through the compensation coil 12 serves as a measure of the strength of the current I.

In the embodiment shown in FIG. 2, the time-measuring device 7 is designed as an analogue comparator 7, which detects the voltage which drops across the first shunt resistor 4, and instead of two signals t₊ and t₋, outputs a combined signal t₊/t₋, which is positive if the voltage across the first shunt resistor 4 is positive, and is negative if the voltage across the first shunt resistor 4 is negative.

In a further embodiment, the time-measuring device 7 can be designed as a microcontroller which detects the voltage which drops across the first shunt resistor 4 via an analogue-to-digital converter, and generates two signals. The first signal specifies the time period t₊ within the last period of the exciting current I_{E} for which the exciting current I_{E} was positive and the second signal specifies the time period t₋ within the last period of the exciting current I_{E} for which the exciting current I_{E} was negative. Alternatively, the microcontroller detects the voltage across the first shunt resistor 4 by means of a comparator input. The comparator input of the microcontroller can thereby be connected directly to a counter of the microcontroller. The time detection then takes place independently of the program sequence within the microcontroller.

The integration means 8 in FIG. 2 comprises a low-pass filter which receives the signal of the analogue comparator 7. If this signal is filtered through the low-pass filter, which has an integrating transfer function, a signal is received which is proportional to the direct current component of the exciting current I_{E} and thus is also proportional to the current I to be measured.

In a further embodiment, the integration means 8 can also be implemented as a microcontroller 8. In a preferred embodiment, a microcontroller comprises both the time-measuring device 7 and the integration means 8. In an embodiment of this type, the integration means 8 is provided as a program module within the microcontroller. The integration means 8 then generates an output signal for each period of the exciting current I_{E}, which signal corresponds to the current strength S_{I} of the exciting current I_{E}. The integration means 8 can generate this signal as an analogue signal via a digital-to-analogue converter of the microcontroller. Alternatively, the integration means 8 can output this signal as a digital signal directly via output pins of the microcontroller or via a digital bus to which the microcontroller is coupled. If the time-measuring device 7 and the integration means 8 are implemented in a current-measuring device without a compensation means 10, as shown in FIG. 1, via a microcontroller, the output signal of the microcontroller can be used directly as a measure of the current strength of the current I. It would also be conceivable to use the signal S_{I} at the integration means 8 as a measure of the current strength I.

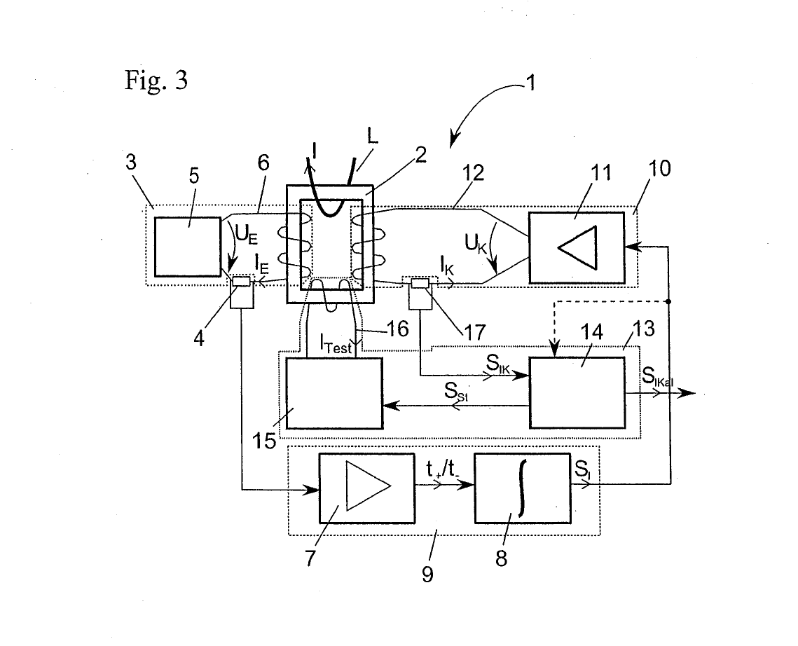

FIG. 3 shows a block diagram of a further embodiment of a current-measuring device 1 according to the invention. In this case, the embodiment of a current-measuring device 1 according to the invention shown in FIG. 3 differs from the embodiment shown in FIG. 2 in that the current strength S_{IK} detected by the second current sensor 17 is conveyed to a calibration device 13. In an alternative embodiment, the signal S_{I} can alternatively or additionally be conveyed to the calibration device 13. This is shown in FIG. 3 by a dashed arrow. The calibration device 13 in this case comprises a control means 14 which is designed to store at least two values of the current strength S_{IK} of the compensating current I_{K} or two values of the signal S_{I} and to generate the difference thereof. In addition, the control means 14 is coupled to a current source 15 which generates a defined current I_{Test}, and is designed to transmit a control signal S_{S1} for start-up to the current source 15. The current source 15 is coupled to a calibration coil 16 which can magnetise the magnetic loop 2 by means of the defined current I_{Test}.

In the embodiment shown in FIG. 3, the control means 14 is implemented as a program-controlled device and determines a calibrated current strength S_{IKal} of the current I which flows through the conductor L. In addition, the control means 14 stores a first value of the current strength S_{IK} whilst the current source 15 is switched off. The control means 14 then generates the control signal S_{S1} for start-up and transmits this to the current source 15. Due to the current I_{Test} flowing through the calibration coil 16, the current strength S_{IK} of the compensating current I_{K} changes. The control means 14 subtracts the changed second value of the current strength S_{IK} of the compensating current I_{K} from the stored first value of the current strength S_{IK} and compares the result of the subtraction to a stored reference value. If the reference value differs from this result, the current-measuring device has a change in gradient. The control means 14 calculates this change in gradient by dividing the reference value by the result of the subtraction. If the control means 14 has calculated a gradient, it determines the calibrated current strength S_{IKal} by multiplying this gradient by the value of the current strength S_{IK}. The control means 14 outputs the value of the calibrated current strength S_{IKal} in digital form as a signal on a digital bus or via signal pins of the control means 14. In addition, the control means 14 can output the value of the calibrated current strength S_{IKal} as an analogue signal via a digital-to-analogue converter.

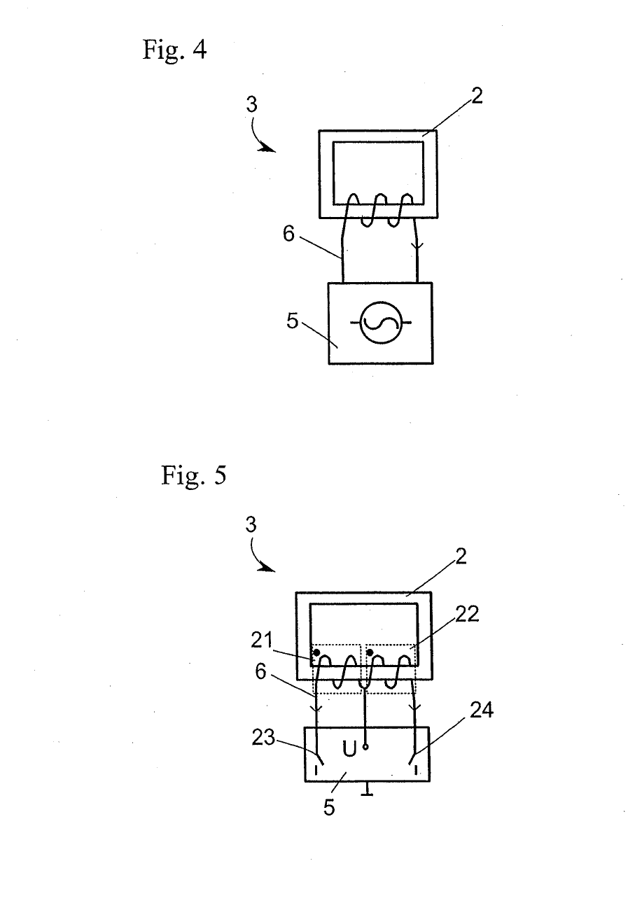

FIG. 4 shows a block diagram of an embodiment of an excitation device 3.

The excitation device 3 in FIG. 4 comprises an excitation generator 5 which is coupled to a coil 6 which is designed to magnetise a magnetic loop 2. The excitation generator 5 is implemented in FIG. 4 as an alternating voltage generator 5 and the exciting coil 6 is coupled to the alternating voltage generator 5 via two electrical connections. The alternating current generator 5 can be implemented as a transformer which generates an alternating voltage, which is suitable for the exciting coil 6, from a source voltage, which is also an alternating voltage. Alternatively, the alternating voltage generator 5 can comprise a full bridge, by means of which the alternating voltage generator 5 can generate an alternating voltage from a direct voltage.

FIG. 5 shows a block diagram of a further embodiment of an excitation device 3 according to the invention. By contrast to the excitation device 3 shown in FIG. 4, the excitation generator 5 in FIG. 5 is coupled to the exciting coil 6 via at least two, for example three or four electrical connections. A first electrical connection contacts the centre of the exciting coil 6 and is connected to a direct current supply voltage in the excitation generator 5. The two further electrical connections each connect one coil end and one coil start of the exciting coil 6 to switches 23 and 24 respectively, within the excitation generator 5. The exciting coil 6 is divided up into two coils 21 and 22 by means of this type of coupling to the excitation generator 5, which coils magnetise the magnetic loop 2 alternately and in different directions. The dots show the two coil starts or the two coil ends of the coil arrangement. If the left switch 23 is closed, this generates a current flow in the left coil 21. If the right switch 24 is closed, this generates a current flow in the right coil 22, in the opposite direction to the current flow in the left coil 21. Since the coils 21 and 22 magnetise the magnetic loop 2 in the same direction, an alternating energization of the left coil 21 and the right coil 22 therefore generates an alternating magnetisation of the magnetic loop 2.

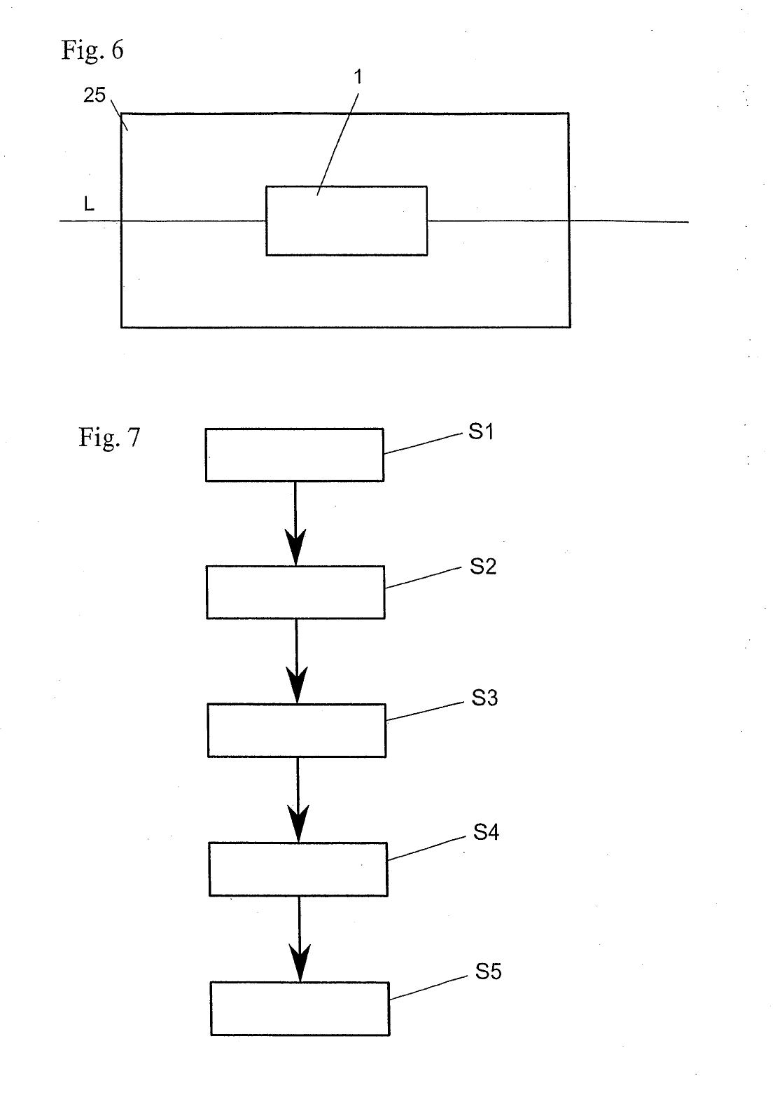

FIG. 6 shows a block diagram of a solar inverter 25 according to the invention. The solar inverter 25 shown in FIG. 6 comprises a current-measuring device 1 and a conductor L which extends through the solar inverter 25 and the current-measuring device 1.

FIG. 7 shows a flow chart of an embodiment of a method according to the invention for detecting a current I.

In a first step S1, a magnetic loop 2 is magnetised by means of a periodic signal U_{E}, the magnetic loop 2 being designed to receive a power supply line L. In the embodiment shown, the power supply line L conveys the current I to be detected.

In a second step S2, the power supply line L is guided through the magnetic loop 2. Depending on the construction, the current-measuring device 1 according to the invention primarily detects currents which flow within the magnetic loop 2. The current-measuring device 1 thereby becomes insensitive to external interference fields.

In a third step S3, the current I to be detected flows through the power supply line L.

In a fourth step S4, an exciting current I_{E} is detected which is generated by means of the periodic signal U_{E} and/or by means of the current I within the excitation device 3.

In a final step S5, a current strength S_{I} of the current I to be detected is determined. This is carried out by determining the shift of the detected exciting current I_{E} on the current axis, which shift is proportional to the current I.

If the exciting current I_{E} is in the form of a sinusoidal signal, this results in a course of the exciting current which, when shown in a time/current graph, is sinusoidal and symmetrical to zero amps when no current I flows. If a current I flows through the power supply line L, the sinusoidal course shifts upwards or downwards in the time/current graph on the basis of the sign of the current I, and the shift can be used as a measure of the current I.

This shift can be determined in different ways. For example, the direct current component of the exciting current I_{E} can be determined. In addition, the ratio of the time period for which the exciting current is positive or negative relative to the cycle duration to the overall cycle duration can be calculated. In a further embodiment, the difference between the time period for which the exciting current I_{E} is positive and the time period for which the exciting current I_{E} is negative can be integrated.

Although the present invention has been described in the above by way of preferred embodiments, it is not limited thereto, but rather can be modified in a wide range of ways. In particular, the invention can be changed or modified in various ways without deviating from the core of the invention.

In an alternative embodiment, the power supply line is guided through the magnetic loop twice, an electrical current consumer being located in the loop of the conductor, which loop appears between a conductor branch leading to the electrical current consumer and a conductor branch returning from the electrical current consumer. In this embodiment, the current-measuring device according to the invention detects a differential current between the leading conductor branch and the returning conductor branch. If the electrical current consumer does not have an insulation fault, the same current flows through the leading conductor branch and the returning conductor branch of the conductor, and the current-measuring device detects a differential current of zero amps. However, as soon as the electrical current consumer has an insulation fault or another electrical fault in which an electrical current flows from the consumer to earth or other electrically conductive devices, the current-measuring device registers a difference between the currents of the leading and returning conductor branches of the conductor. The output of the current-measuring device then corresponds to this differential current.

### LIST OF REFERENCE SIGNS

1 Current-measuring device
2 Magnetic loop
3 Excitation device
4 First current sensor
5 Excitation generator
6 Exciting coil
7 Time-measuring device
8 Integration means
9 Determining means
10 Compensation means
11 Compensation generator
12 Compensation coil
13 Calibration device
14 Control means
15 Current source
16 Calibration coil
17 Second current sensor
21 Left coil
22 Right coil
23 Left switch
24 Right switch
25 Solar inverter
L Power supply line
I Current
U_{E} Periodic signal, voltage signal
I_{E} Exciting current
t₊, t₋ Time periods
t₊/t₋ Time period signal
S_{I} Current strength
S_{IK} Current strength
S_{IKal} Calibrated current strength
U_{K} Compensating voltage
I_{K} Compensating current
S_{St} Control signal
I_{Test} Defined current
S1-S5 Method steps

1. A current-measuring device for detecting a current flowing through a power supply line, comprising:
a magnetic loop for receiving the power supply line;
an excitation device which is designed to magnetise the magnetic loop by means of a periodic signal of such a type that the current constantly fluctuates between two saturation limits;
a first current sensor which is designed to detect an exciting current flowing in the excitation device due to the periodic signal or the current to be detected;
a determining means which determines a shift of the detected exciting current on the current axis caused by the current and which derives therefrom the current strength of the current to be detected.

2. The device of claim 1, wherein the excitation device further comprising:
an excitation generator which generates a periodic voltage as a periodic signal, and
an exciting coil which is designed to magnetise the magnetic loop by means of the periodic voltage.

3. The device of claim 1, wherein the determining means further comprising:
a time-measuring device which, for each period of the periodic signal, measures a first time period in which the detected exciting current has a positive value, and which, for each period of the periodic signal, measures a second time period in which the detected exciting current has a negative value, and
an integration means which integrates a difference between the first time period measured and the second time period measured as a measure of the current to be detected.

4. The device of claim 1, wherein the determining means comprises a filter device which filters a direct current component of the detected exciting current out of the detected exciting current as a measure of the current to be detected.

5. The device of claim 1, wherein a compensation means is provided which is designed to additionally magnetise the magnetic loop in the opposite direction on the basis of the detected current strength.

6. The device of claim 1, wherein the compensation means further comprising:
a compensation generator which is designed to generate a compensating voltage on the basis of the current strength, and
a compensation coil which is designed to additionally magnetise the magnetic loop in the opposite direction by means of the generated compensating voltage.

7. The device of claim 1, wherein a calibration device is provided which is designed to magnetise the magnetic loop and to generate a calibrated current strength of the current to be measured by the current-measuring device on the basis of the compensating current being set due to the compensating voltage in the compensation coil.

8. The device of claim 1, wherein the compensation means comprises a second current sensor which is designed to detect the compensating current flowing in the compensation coil.

9. The device of claim 1, wherein the calibration device further comprising:
a control means which periodically stores a first current strength of the compensating current at predetermined time intervals and then generates a control signal for start-up;
a current source which generates a defined current on the basis of the control signal;
a calibration coil which is designed to additionally magnetise the magnetic loop on the basis of the defined current;
wherein the control means being designed to store a second current strength of the compensating current when the magnetic loop is magnetised by means of the defined current, and the control means being designed to determine a calibrated current strength from the difference between the first stored current strength and the second stored current strength.

10. The device of claim 1, wherein the integration means is designed as an analogue circuit.

11. The device of claim 1, wherein an integrated circuit or a program-controlled device is provided which comprises the integration means.

12. The device of claim 1, wherein the magnetic loop is designed as a magnetic loop without an air gap.

13. The device of claim 1, wherein the exciting coil is designed as a single or double coil.

14. A solar inverter, in particular a transformerless solar inverter, comprising a current-measuring device according to claim 1.

15. The inverter of claim 14, which is configured to be a transformerless solar inverter.

16. A method for detecting a current, comprising the steps of:
magnetizing a magnetic loop for receiving a power supply line by means of a periodic signal via an excitation device;
guiding a power supply line through the magnetic loop;
energising the power supply line with the current to be detected;
detecting an exciting current which flows in the excitation device due to the periodic signal or due to the current;
deriving a current strength of the current to be detected from the shift of the detected exciting current on the current axis.

17. The method of claim 16, wherein deriving the current strength comprises the further steps of:
measuring a first time period in which the exciting current has a positive value, and a second time period in which the exciting current has a negative value;
integrating the difference between the first time period and the second time period; and
determining the current strength from the integration result.

18. The method of claim 16, comprising the further steps of:
generating a compensating voltage by means of a compensation generator on the basis of the determined current strength;
magnetizing the magnetic loop via a compensation coil by means of the compensating voltage.

19. The method of claim 16, comprising the further steps of:
periodically storing a first current strength of the compensating current, the magnetic loop not being additionally magnetised by means of a defined test current;
subsequently starting up a current source which generates the defined test current;
magnetizing the magnetic loop via a calibration coil by means of the defined test current;
storing a second current strength of the compensating current which flows in the compensation coil, the magnetic loop additionally being magnetised by means of the defined test current;
determining a calibrated current strength by means of the difference between the first current strength and the second current strength of the compensating current via the control means.

20. The method of claim 16, comprising at least one of:
a first operating mode in which direct currents are detected by means of the current-measuring device;
a second operating mode in which alternating currents are detected by means of the current-measuring device; and
a third operating mode is provided in which direct and alternating currents are detected at the same time by means of the current-measuring device.
